(19) United States
(12) Patent Application Publication
(10) Pub. No.: US 2013/0279282 A1
(43) Pub. Date: Oct. 24, 2013

(54) E-FUSE ARRAY CIRCUIT

(71) Applicant: SK HYNIX INC., Gyeonggi-do (KR)

(72) Inventor: Kwi-Dong KIM, Gyeonggi-do (KR)

(73) Assignee: SK HYNIX INC., Gyeonggi-do (KR)

(21) Appl. No.: 13/712,631

(22) Filed: Dec. 12, 2012

(30) Foreign Application Priority Data
Apr. 19, 2012 (KR) 10-2012-0040961

(51) Int. Cl. G11C 17/16; G11C 7/06

(52) U.S. Cl. CPC G11C 17/16; G11C 7/062
USPC 365/207; 365/225.7

(57) ABSTRACT

An e-fuse array circuit includes a first select transistor configured to have a gate terminal connected to a first select line and have a first terminal connected to a first bit line, a first e-fuse transistor configured to have a gate terminal connected to a common program/read line and have a first terminal connected to a second terminal of the first select transistor, a second select transistor configured to have a gate terminal connected to a second select line and have a first terminal connected to the first bit line, and a second e-fuse transistor configured to have a gate terminal connected to the common program/read line and have a first terminal connected to a second terminal of the second select transistor.

### CROSS-REFERENCE TO RELATED APPLICATIONS

The present application claims priority of Korean Patent Application No. 10-2012-0040961, filed on Apr. 19, 2012, which is incorporated herein by reference in its entirety.

### BACKGROUND

1. Field

An exemplary embodiment of the present invention relates to an e-fuse array circuit, and more particularly, to technology for increasing a stability of an operation of an e-fuse array circuit, particularly, a program operation.

2. Description of the Related Art

In general, a fuse can be programmed in a wafer state because data is determined by whether the fuse has been cut or not by a laser, but the fuse cannot be programmed after a wafer is mounted on a package.

An e-fuse is used to overcome this disadvantage. The e-fuse refers to a fuse for storing data by changing resistance between a gate and a drain/source a transistor.

FIG. 1 is a diagram showing an e-fuse formed of a transistor operating as a resistor or a capacitor.

Referring to FIG. 1, the e-fuse is implemented with a transistor T. A power source voltage is supplied to a gate G of the transistor T, and a ground voltage is supplied to a drain/source D/S of the transistor T.

When a voltage against which the transistor T may withstand is supplied to the gate G, the e-fuse operates as a capacitor C. Accordingly, there is no current that flows through the gate G and the drain/source D/S. When a high voltage against which the transistor T may not withstand is supplied to the gate G, a gate oxide of the transistor T is broken, and thus, the gate G and the drain/source D/S are shorted. As a result, the e-fuse operates as a resistor R. Accordingly, an electric current flows across the gate G and the drain/source D/S. In other words, the data of the e-fuse is recognized based on a resistance value between the gate G and the drain/source D/S of the e-fuse.

Here, two methods may be used for recognizing the data of the e-fuse: (1) a first method of directly recognizing the data of the e-fuse by increasing a size of the transistor T without an additional sensing operation, or (2) a second method of recognizing the data of the e-fuse by sensing an electric current that flows through the transistor T using an amplifier while reducing the size of the transistor T. The two methods described above have a limitation in view of a circuit area because (1) the size of the transistor T that forms the e-fuse must be increased or (2) the amplifier for amplifying data must be provided in each e-fuse.

As disclosed in U.S. Pat. No. 7,269,047, researches are being carried out on schemes for reducing an area occupied by e-fuse circuit in such a way as to configure the e-fuses in an array form.

FIG. 2 is a construction diagram illustrating an e-fuse array 1000 formed of conventional e-fuse cells.

Referring to FIG. 2, the e-fuse array 1000 includes e-fuse cells 11 to 26 arranged in N rows and M columns, The e-fuse cells 11 to 26 include respective program elements M1 to M16 and respective switch elements S1 to S16. Each of the program elements M1 to M16 is an e-fuse formed of a transistor (Hereinafter, referring to as “an e-fuse transistor”) that has the properties of a resistor or a capacitor depending on whether the program element has been ruptured. That is, each of the e-fuse transistors M1 to M16 may be considered as a resistive memory element for storing data depending on the amount of resistance. The switch elements S1 to S16 electrically couple the program elements M1 to M16 to column lines BL1 to BLM under the control of row lines SWL1 to SWLN.

Hereinafter, it is assumed that a second row line SWL2 is selected and an M^{th} column lines BLM is selected, and thus the e-fuse cell 18 is selected. Voltages supplied to the selected e-fuse cell 18 and the remaining unselected e-fuse cells 11 to 17 and 19 to 26 when program and read operations are performed are described.

Program Operation

The second row line SWL2 is activated, and the remaining row lines SWL1 and SWL3 to SWLN are deactivated. In response thereto, the switch elements S5 to S8 are turned on, and the switch elements S1 to S4 and S9 to S16 are turned off. A boost voltage that is enough to rupture the gate oxide of the e-fuse transistor, i.e., a voltage generated by pumping a power supply voltage, is supplied to a second program/read line PRWL2, and a low voltage, i.e., a ground voltage, is supplied to the remaining program/read lines PRWL1 and PRWL3 to PRWLN. The selected M^{th} column line BLM is connected to a data access circuit (not shown), and the unselected column lines BL1 to BLM-1 are floated. The data access circuit drives the selected column line BLM to a ‘low’ level so that the program element M8 of the selected e-fuse cell 18 is ruptured when data to be programmed is a first data (for example, ‘1’) and drives the selected column line BLM to a level so that the program element M8 of the selected e-fuse cell 18 is not ruptured when the data to be programmed is a second data (for example, ‘0’). The unselected column lines BL1 to BLM-1 are floated, and thus the program elements M5 to M7 are not ruptured although the boost voltage is supplied to gates thereof.

Read Operation

The second row line SWL2 is activated, and the remaining row lines SWL1 and SWL3 to SWLN are deactivated. In response thereto, the switch elements S5 to S8 are turned on, and the switch elements S1 to S4 and S9 to S16 are turned off Voltage suitable for the read operation, a power supply voltage (VDD), is supplied to the second program/read line PRWL2, and a low voltage, i.e., a ground voltage, is supplied to the remaining program/read lines PRWL1 and PRWL3 to PRWLN. The selected M^{th} column line BLM is connected to the data access circuit, and the unselected column lines BL1 to BLM-1 are floated. When an electric current flows through the selected M^{th} column line BLM, the data access circuit determines that the program element M8 has been ruptured, and thus recognizes the data of the selected e-fuse cell 18 as ‘1’. When an electric current does not flow through the selected M^{th} column line BLM, the data access circuit determines that the program element M8 has not been ruptured, and thus recognizes the data of the selected e-fuse cell 18 as ‘0’.

Although one column line BLN has been illustrated as being selected from the column lines BL1 to BLN, several column lines may be selected at once. That is, several e-fuse cells belonging to one row can be programmed or read at the same time.

FIG. 3 is a graph illustrating a change of a voltage level in a process of rupturing the selected program element M8 shown in FIG. 2.

In the above-described program operation, when a boost voltage VPP having a voltage level higher than a power supply voltage (VDD) is supplied to a gate of the selected program element M8, that is, the e-fuse transistor M8, and a low voltage, i.e., a ground voltage, is supplied to a drain/source of the selected program element M8, the e-fuse transistor M8 starts being ruptured (subject to breakdown). At this time, a large amount of current instantaneously flows from the gate to the drain/source of the selected program element M8. As a result, the level of the voltage supplied to the gate of the e-fuse transistor M8 instantaneously drops to a threshold voltage level VB or lower at which the e-fuse transistor M8 may be subject to breakdowns As a result, after the breakdown is started, it is difficult to expect additional breakdown or soft breakdown, because the e-fuse transistor M8 may not have enough time to be subject to breakdown.

### SUMMARY

Exemplary embodiments of the present invention are directed to provide an e-fuse array circuit in which a selected e-fuse has enough time to be subject to breakdown when the selected e-fuse is ruptured.

In accordance with an embodiment of the present invention, an e-fuse array circuit includes a first select transistor configured to have a gate terminal connected to a first select line and have a first terminal connected to a first bit line, a first e-fuse transistor configured to have a gate terminal connected to a common program/read line and have a first terminal connected to a second terminal of the first select transistor, a second select transistor configured to have a gate terminal connected to a second select line and have a first terminal connected to the first bit line and a second e-fuse transistor configured to have a gate terminal connected to the common program/read line and have a first terminal connected to a second terminal of the second select transistor.

In accordance with another embodiment of the present invention, an e-fuse array circuit includes a plurality of e-fuse cells disposed in a form of M by N matrix, and divided into N groups extended toward an Y direction, each group comprising M e-fuse cells, wherein each of the e-fuse cells comprises a select transistor and an e-fuse transistor, and the select transistors of the e-fuse cells in the same group has a gate terminal coupled to a corresponding select line and a source/drain path between a respective bit line and a respective e-fuse transistor while all of the e-fuse transistors in the same group have a gate terminal coupled to a common program/read line.

### BRIEF DESCRIPTION OF THE DRAWINGS

FIG. 1 is a diagram illustrating an e-fuse formed of a transistor operating as a resistor or a capacitor.

FIG. 2 is a construction diagram illustrating an e-fuse cell array formed of conventional e-fuses.

FIG. 3 is a graph illustrating a change of a voltage level in a process of rupturing a selected program element shown in FIG. 2.

FIG. 4 is a diagram illustrating a case where an additional capacitor is connected to an e-fuse transistor to be programmed.

FIG. 5 is a diagram illustrating an e-fuse array circuit in accordance with an embodiment of the present invention.

FIG. 6 is a graph illustrating a change of a voltage level in a process in which a selected e-fuse transistor shown in FIG. 5 is ruptured.

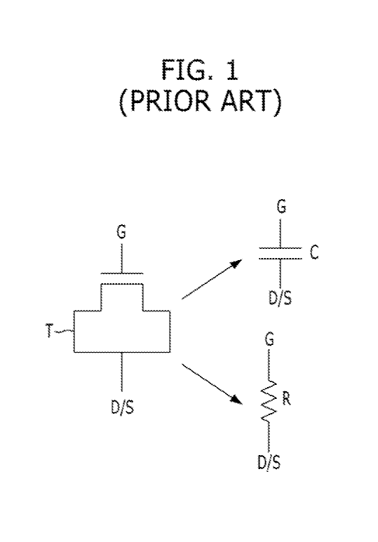

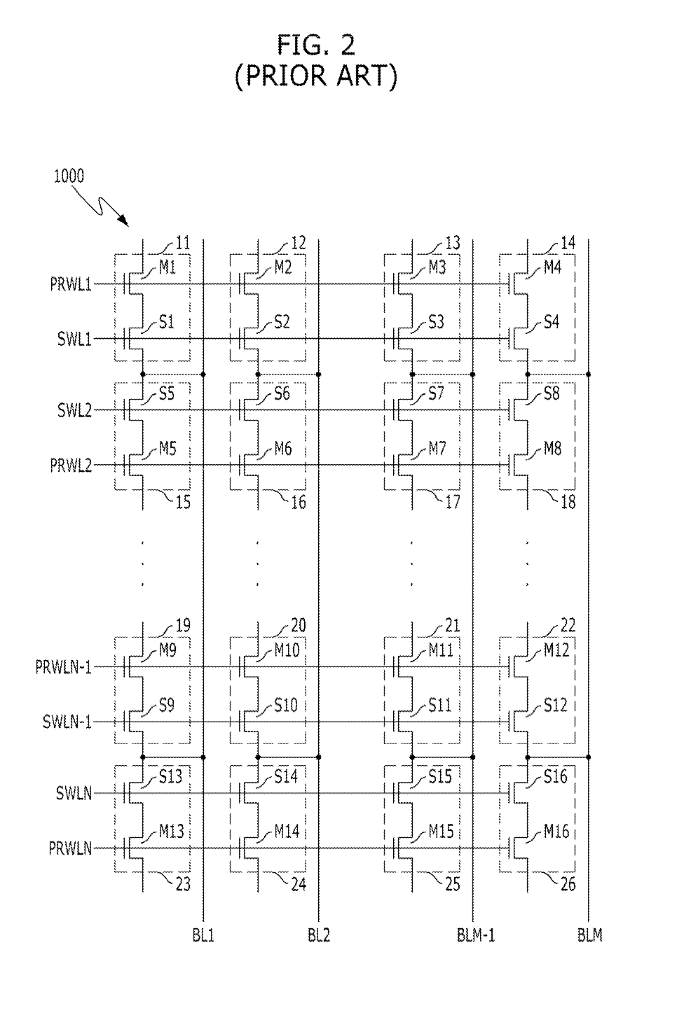

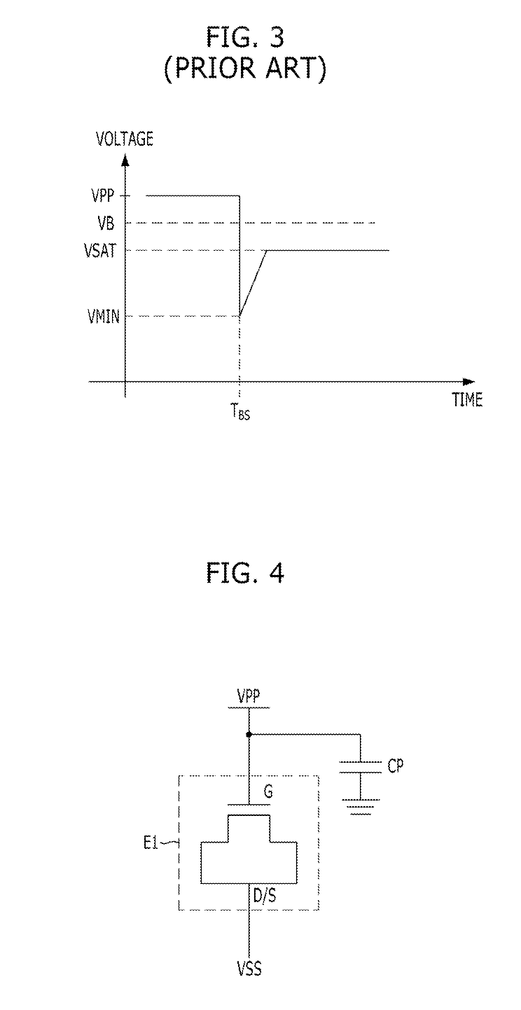

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. In this specification, ‘connected/coupled’ represents that one component is directly coupled to another component or indirectly coupled through another component. In this specification, a singular form may include a plural form as long as it is not specifically mentioned in a sentence.

FIG. 4 is a diagram illustrating a case where an additional capacitor is connected to an e-fuse transistor E1 to be programmed.

Referring to FIG. 4, when the additional capacitor CP is connected to the e-fuse transistor E1, a change in a voltage level of a gate terminal G of the e-fuse transistor E1 after the e-fuse transistor E1 starts being subject to breakdown is inhibited. That is, the capacitor CP helps the voltage level of the gate terminal G of the e-fuse transistor E1 to change slowly.

In accordance with the present invention, when a selected e-fuse transistor is ruptured, the remaining unselected e-fuse transistors (that is, e-fuse transistors not the subject of program) perform a function, such as that of the capacitor CP shown in FIG. 4.

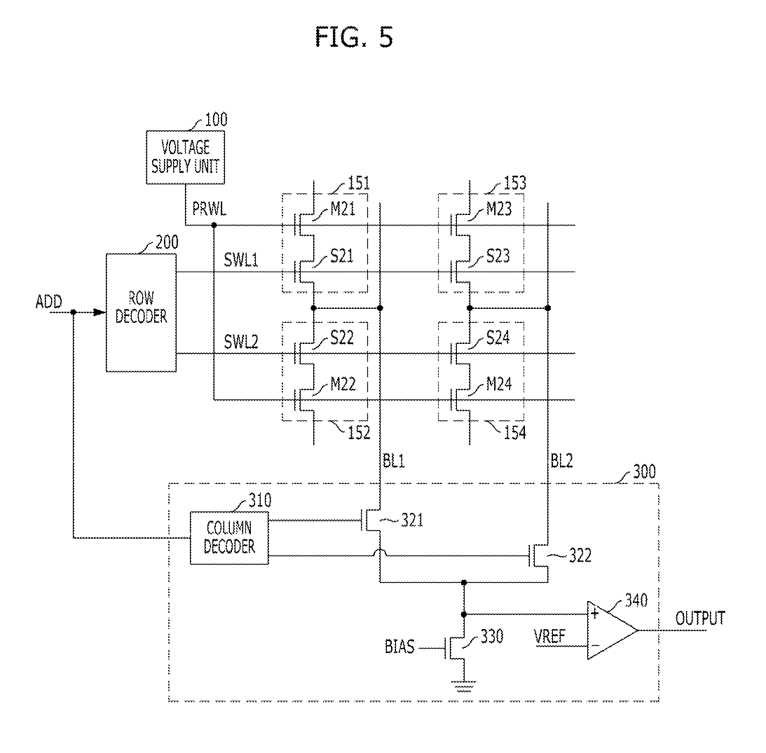

FIG. 5 is a diagram illustrating an e-fuse array circuit in accordance with an embodiment of the present invention.

Referring to FIG. 5, the e-fuse array circuit includes first to fourth e-fuse cells 151 to 154, a voltage supply unit 100, a row decoder 200, and a column control circuit 300.

The e-fuse array circuit may include N×M e-fuse cells. However 2×2 e-fuse cells are illustrated in FIG. 5, for convenience of description,

The first e-fuse cell 151 includes a first select transistor S21 and a first e-fuse transistor M21. The first select transistor S21 has a gate terminal connected to a first select line SWL1 and has one terminal connected to a first bit line BL1. An example in which the first select transistor S21 is implemented with an NMOS transistor has been illustrated in FIG. 5, for convenience of description. The first e-fuse transistor M21 has a gate terminal connected to a common program read line PRWL and has one terminal connected to the other terminal of the first select transistor S21. Furthermore, the other terminal of the first e-fuse transistor M21 may be floated.

The second e-fuse cell 152 includes a second select transistor S22 and a second e-fuse transistor M22. The second select transistor S22 has a gate terminal connected to a second select line SWL2 and has one terminal connected to the first bit line BL1. An example in which the second select transistor S22 is implemented with an NMOS transistor has been illustrated in FIG. 5, for convenience of description. The second e-fuse transistor M22 has a gate terminal connected to the common program/read line PRWL and has one terminal connected to the other terminal of the second select transistor S22. Furthermore, the other terminal of the second e-fuse transistor M22 may be floated.

The third e-fuse cell 153 includes a third select transistor S23 and a third e-fuse transistor M23. The third select transistor S23 has a gate terminal connected to the first select line SWL1 and has one terminal connected to a second bit line BL2. An example in which the third select transistor S23 is implemented with an NMOS transistor has been illustrated in FIG. 5, for convenience of description. The third e-fuse transistor M23 has a gate terminal connected to the common program/read line PRWL and has one terminal connected to the other terminal of the third select transistor S22. Furthermore, the other terminal of the third e-fuse transistor M23 may be floated.

The fourth e-fuse cell 154 includes a fourth select transistor S24 and a fourth e-fuse transistor M24. The fourth select transistor S24 has a gate terminal connected to the second select line SWL2 and has one terminal connected to the second bit line BL2. An example in which the fourth select transistor S24 is implemented with an NMOS transistor has been illustrated in FIG. 5, for convenience of description. The fourth e-fuse transistor M24 has a gate terminal connected to the common program/read line PRWL and has one terminal connected to the other terminal of the fourth select transistor S24. Furthermore, the other terminal of the fourth e-fuse transistor M24 may be floated.

As shown in FIG. 5, the first to fourth e-fuse transistors M21 to M24 share one program/read line PRWL.

The voltage supply unit 100 supplies the common program/read line PRWL with a boost voltage (hereinafter, referring to as “a program voltage”) generated by pumping a power supply voltage VDD enough to rupture gate oxides of the e-fuse transistors M21 to M24 when a program operation, that is, an operation of rupturing an e-fuse transistor, is performed, and supplies the common program/read line PRWL with a voltage suitable for a read operation, i.e., the power supply voltage VDD (hereinafter, referring to as “a read voltage”) when the read operation is performed.

The row decoder 200 decodes an input address ADD and enables a corresponding one of the first and the second select lines SWL1 and SWL2 in response to the decoded address ADD so that the select transistor of the corresponding select line is turned on. For example, if the input address ADD corresponds to the first select line SWL1, the row decoder 200 enables the first select line SWL1 in a high level, with the result that the first select transistor S21 and the third select transistor S23 connected to the first select line SWL1 are turned on.

The column control circuit 300 includes a column decoder 310, a current limiter 330, and a sense amplifier 340. The column decoder 310 decodes the input address ADD and connects one of the first and the second bit lines BL1 and BL2, which corresponds to the input address ADD, with the current limiter 330. For example, if the first bit line BL1 corresponds to the input address ADD, the column decoder 310 turns on a first switch 321 connected to the first bit line BL1 so that the first bit line BL1 is connected to the current limiter 330. The current limiter 330 is implemented with a transistor that is controlled by a bias voltage BIAS. FIG. 5 illustrates an exemplary embodiment in which the current limiter 330 is implemented with an NMOS transistor, for convenience of description. The current limiter 330 functions to sink the current of a bit line, selected from the first and the second bit lines BL1 and BL2, into a ground voltage terminal. The sense amplifier 340 compares a voltage at a node of the current miter 330 with a reference voltage VREF and senses data based on a result of the comparison. If selected e-fuse cells are ruptured by the row decoder 200 and the column decoder 310, the sense amplifier 340 generates output data OUTPUT of a high level because an electric current flows through the current limiter 330. If the selected e-fuse cells are not ruptured, the sense amplifier 340 generates the output data OUTPUT of a low level because an electric current does not flow through the current limiter 330.

Assuming that the second e-fuse cell 152 of the first to fourth e-fuse cells 151 to 154 has been selected hereinafter, the program and read operations of the e-fuse array circuit are described.

Program Operation

The voltage supply unit 100 supplies a program voltage to the common program/read line PRWL when a program operation is performed. The program voltage is supplied to the gate terminals of the first to fourth e-fuse transistors M21 to M24, because the first to fourth e-fuse transistors M21 to M24 share one program/read line PRWL.

Meanwhile, the row decoder 200 decodes the address ADD and enables the selected second select line SWL2 in a high level. In response thereto, the second select transistor S22 and the fourth select transistor S24 connected to the second select line SWL2 are turned on.

The column decoder 310 decodes the address ADD and couples the selected first bit line BL1 and the current limiter 330. The current limiter 330 sinks the current of the first bit line BL1 into the ground voltage terminal in response to the bias voltage BIAS of a high level. As a result, a voltage level of the first bit line BL1 is connected to the ground voltage terminal, thus becoming a low level. The first bit line BL1 having a low voltage is supplied to one terminal of the second e-fuse transistor M22 through the second select transistor S22 that has been turned on.

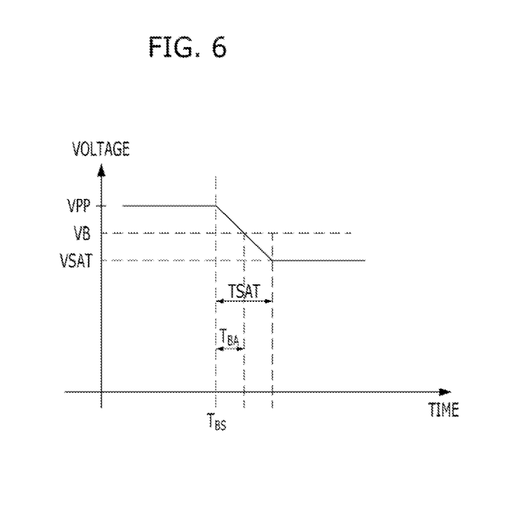

As a result, the program voltage is supplied to the gate terminal of the second e-fuse transistor M22 and the ground voltage is supplied to one terminal of the second e-fuse transistor M22 so that the second e-fuse transistor M22 starts being ruptured (or subject to breakdown). At this time, the remaining unselected e-fuse transistors M21, M23 and M24 are not ruptured, because the drain/source terminals thereof are floated although the program voltage is supplied to the gate terminals of the e-fuse transistors M21, M23 and M24. Meanwhile, each of the remaining unselected e-fuse transistors M21, M23 and M24, that is, each of the e-fuse transistors M21, M23 and M24 that have not been ruptured, performs a function, such as that of the capacitor CP shown in FIG. 4 in relation to the selected second e-fuse transistor M22. As a result, although the second e-fuse transistor M22 starts being subject to breakdown, a voltage level of the gate terminal of the second e-fuse transistor M22 does not suddenly change. This may be checked from a graph that illustrates a change in the voltage level of the gate terminal of the second e-fuse transistor M22 shown in FIG. 6.

Referring to FIG. 6, it may be checked that after a point of time T_{BS} at which the selected second e-fuse transistor M22 starts being subject to breakdown, a voltage level of the gate terminal of the second e-fuse transistor M22 slowly drops to a saturation voltage VSAT, This is because the remaining unselected e-fuse transistors M21, M23, and M24 performs a function, such as that of the capacitor CP shown in FIG. 4 in relation to the selected second e-fuse transistor M22. Duration T_{BA} for which a voltage level of the gate terminal of the second e-fuse transistor M22 is higher than a critical voltage level VB at which the second e-fuse transistor M22 may be subject to breakdown is sufficiently secured in duration TSAT for which the second e-fuse transistor M22 is taken to reach the saturation voltage VSAT from the point of time T_{BS} at which the selected second e-fuse transistor M22 starts being subject to breakdown. Accordingly, the second e-fuse transistor M22 may be subject to additional breakdown or soft breakdown for the duration T_{BA}.

Read Operation

The voltage supply unit 100 supplies a read voltage to the common program/read line PRWL when a read operation is performed. The read voltage is supplied to the gate terminals of the first to fourth e-fuse transistors M21 to M24, because the first to fourth e-fuse transistors M21 to M24 share the common program/read line PRWL.

Meanwhile, the row decoder 200 decodes the address ADD and enables the selected second select line SWL2 in a high level. In response thereto, the second select transistor S22 and the fourth select transistor S24 connected to the second select line SWL2 are turned on.

The column decoder 310 decodes the address ADD and connects the selected first bit line BL1 with the current limiter 330. The current limiter 330 sinks the current of the first bit line BL1 into the ground voltage terminal in response to the bias voltage BIAS of a high level.

If the second e-fuse transistor M22 has been ruptured, the sense amplifier 340 generates the output data OUTPUT of a high level, because an electric current flows through the current limiter 330. If the second e-fuse transistor M22 has not been ruptured, the sense amplifier 340 generates the output data OUTPUT of a low level, because an electric current does not flow through the current limiter 330.

In accordance with the present invention, a voltage level of the gate terminal of a selected e-fuse transistor is slowly changed after the selected e-fuse transistor is subject to breakdown because each of unselected e-fuse transistors plays a role of a capacitor when the selected e-fuse transistor is ruptured. As a result, the time that the selected e-fuse transistor may be subject to breakdown may be secured sufficiently, so that additional breakdown or soft breakdown may be possible after the selected e-fuse transistor is subject to breakdown. Furthermore, the area of the e-fuse array circuit may be reduced because additional capacitors are not added.

While the present invention has been described with respect to the specific embodiments, it will be apparent to those skilled in the art that various changes and modifications may be made without departing from the spirit and scope of the invention as defined in the following claims.

What is claimed is:

1. An e-fuse array circuit comprising:
a first select transistor configured to have a gate terminal connected to a first select line and have a first terminal connected to a first bit line;
a first e-fuse transistor configured to have a gate terminal connected to a common program/read line and have a first terminal connected to a second terminal of the first select transistor;
a second select transistor configured to have a gate terminal connected to a second select line and have a first terminal connected to the first bit line; and
a second e-fuse transistor configured to have a gate terminal connected to the common program/read line and have a first terminal connected to a second terminal of the second select transistor.

2. The e-fuse array circuit of claim 1, further comprising:
a third select transistor configured to have a gate terminal connected to the first select line and have a first terminal connected to a second bit line;
a third e-fuse transistor configured to have a gate terminal connected to the common program/read line and have a first terminal connected to a second terminal of the third select transistor;
a fourth select transistor configured to have a gate terminal connected to the second select line and have a first terminal connected to the second bit line; and
a fourth e-fuse transistor configured to have a gate terminal connected to the common program/read line and have a first terminal connected to a second terminal of the fourth select transistor.

3. The e-fuse array circuit of claim 2, wherein the common program/read line is supplied with a program voltage when a program operation is performed, and is supplied with a read voltage having a lower voltage level than the program voltage when a read operation is performed.

4. The e-fuse array circuit of claim 3, wherein the program voltage has a higher voltage level than a power supply voltage, and the read voltage has a voltage level substantially the same as the power supply voltage.

5. The e-fuse array circuit of claim 2, further comprising:
a voltage supply unit configured to supply the common program/read line with a program voltage when a program operation is performed, and supply the common program/read line with a read voltage having a lower voltage level than the program voltage when a read operation is performed.

6. The e-fuse array circuit of claim 2, wherein,
when a program operation is performed, one of the first select line and the second select line, corresponding to one to be programmed from among the first to fourth e-fuse transistors, is activated, and
when a read operation is performed, one of the first select line and the second select line, corresponding to one to be read from among the first to fourth e-fuse transistors, is activated.

7. The e-fuse array circuit of claim 2, further comprising:
a row decoder configured to enable one of the first select line and the second select line, corresponding to an address, when a program operation is performed or a read operation is performed.

8. The e-fuse array circuit of claim 2, wherein,
when a program operation is performed, a low voltage is supplied to one of the first bit line and the second bit line, corresponding to one to be programmed from among the first to fourth e-fuse transistors, and
when a read operation is performed, the low voltage is supplied to one of the first bit line and the second bit line, corresponding to one to be read from among the first to fourth e-fuse transistors.

9. The e-fuse array circuit of claim 2, further comprising:
a column control circuit configured to connect one of the first bit line and the second bit line, corresponding to an address, with a ground voltage terminal when a program operation is performed or a read operation is performed.

10. The e-fuse array circuit of claim 9, wherein the column control circuit comprises:
a column decoder configured to decode the address;
a current limiter configured to function to sink current of the first and the second bit lines into a ground voltage terminal;
a switching unit configured to connect a corresponding one of the first and the second bit lines with the current limiter in response to an output of the column decoder; and
a sense amplifier configured to compare a voltage at a node of the current limiter with a reference voltage to sense data based on a result of the comparison.

11. An use array circuit comprising:
a plurality of e-fuse cells disposed in a form of M by N matrix, and divided into N groups extended toward an Y direction, each group comprising M e-fuse cells,
wherein each of the e-fuse cells comprises a select transistor and an e-fuse transistor, and the select transistors of the e-fuse cells in the same group has a gate terminal coupled to a corresponding select line and a source/drain path between a respective bit line and a respective e-fuse transistor while all of the e-fuse transistors in the same group have a gate terminal coupled to a common program/read line.

12. The e-fuse array circuit of claim 11, further comprising:
a voltage supply unit configured to supply the common program/read line with a program voltage when a program operation is performed, and supply the common program/read line with a read voltage when a read operation is performed;
a row decoder configured to enable the select lines of the e-fuse cells in the same group corresponding to an address when the program or read operation is performed; and
a column control circuit configured to connect one of the bit lines, corresponding to the address, with a ground voltage terminal when the program or read operation is performed.

13. The e-fuse array circuit of claim 12, wherein the column control circuit comprises:
a column decoder configured to decode the address;
a current limiter configured to function to sink current of the first and the second bit lines into the ground voltage terminal;
a switching unit configured to connect a corresponding one of the first and the second bit lines with the current limiter in response to an output of the column decoder; and
a sense amplifier configured to compare a voltage at a node of the current limiter with a reference voltage to sense data based on a result of the comparison.

14. The e-fuse array circuit of claim 11, wherein,
when a program operation is performed, the common program/read line is supplied with a program voltage having a higher voltage level than a power supply voltage, and
when a read operation is performed, and the program/read line is supplied with a read voltage having a lower voltage level than the program voltage.
